(19) United States
(12) Patent Application Publication
(10) Pub. No.: US 2025/0040288 A1
(43) Pub. Date: Jan. 30, 2025

(54) Monolithic Optical Transformer

(71) Applicant: Lumileds LLC, San Jose, CA (US)

(72) Inventors: Wouter Anthon Soer, Utrecht (NL); Isaac Wildeson, Nashua, NH (US); Ronald Bonne, Plainfield, IL (US)

(73) Assignee: Lumileds LLC, San Jose, CA (US)

(21) Appl. No.: 18/715,786

(22) PCT Filed: Dec. 5, 2022
(86) PCT No.: PCT/US2022/080925

§ 371 Date: Jun. 3, 2024

Related U.S. Application Data
(60) Provisional application No. 63/287,325, filed on Dec. 8, 2021.

(51) Int. Cl. H01L 31/173; H01L 27/15; H01L 31/18; H01L 33/00; H01L 33/06; H01L 33/20

(52) U.S. Cl. CPC H01L 31/173; H01L 27/153; H01L 33/06; H01L 33/20; H01L 31/1856; H01L 33/007

(57) ABSTRACT

Provided are optical transformer devices having a high power efficiency. The device architecture provides uniform current spreading to minimize efficiency droop. The quantum well designs are optimized for both light-emitting diode (LED) and photo diode (PD) operation. A low-loss optical cavity allows efficient transfer of light from the LED junction to the PD junction. The architecture provides a low-loss voltage up- and down-conversion and provides compatibility with production-grade epitaxial growth and wafer fabrication processes.

### TECHNICAL FIELD

Embodiments of the disclosure generally relate to optoelectronic devices and methods of manufacturing the same. More particularly, embodiments are directed to apparatus and methods for integrating a light emitting diode (LED) and a photodiode (PD) in a single-monolithic semiconductor die.

### BACKGROUND

When LEDs are used as photodiodes, the process of photon absorption is reversed to that of photon creation in an LED. By combining a LED and a photodiode, where the emission of the LED is detected by the photodiode, an opto-coupler may be created. This is a device which has widespread use in the electronics industry and in data communication.

There is ongoing effort to improve the efficiency and power capability of the optical coupling in these devices. Accordingly, there is a need for a monolithic LED/Photodiode pair that allows light generation and detection within the same semiconductor device such that optical losses which are usually associated with optical transitions between dielectric media with different refractive indices, are minimized. Such a device would allow for an opto-coupler with an overall quantum efficiency, between LED and photodiode, which is dominated by the internal quantum efficiencies. The improved efficiency enables transfer of larger power quantities than state-of-the-art optocouplers and accordingly much broader functionality.

### SUMMARY

One or more embodiments are directed to a monolithic optical device. In one or more embodiments, a monolithic optical device comprises: a light-emitting diode (LED) junction; a photo diode (PD) junction; and a semi-insulating layer separating the light-emitting diode (LED) junction and the photo diode (PD) junction, wherein the light-emitting diode (LED) junction, the photo diode (PD) junction, and the semi-insulating layer are stacked vertically.

Additional embodiments are directed to a monolithic optical device. In one or more embodiments, a monolithic optical device comprises: a light-emitting diode (LED) junction; a photo diode (PD) junction; a tunnel junction, and a contact shared by the light-emitting diode (LED) junction and the photo diode (PD) junction, wherein the light-emitting diode (LED) junction, the photo diode (PD) junction, and the tunnel junction are stacked vertically.

Further embodiments are directed to a monolithic optical device. In one or more embodiments, a monolithic optical device comprises: a light-emitting diode (LED) junction; a first photo diode (PD) junction; a second photo diode (PD) junction; a tunnel junction separating the first photo diode (PD) junction and the second photo diode (PD) junction; and a semi-insulating layer separating the light-emitting diode (LED) junction and the first photo diode (PD) junction, wherein the light-emitting diode (LED) junction, the first photo diode (PD) junction, the second photo diode (PD) junction, the tunnel junction, and the semi-insulating layer are stacked vertically.

Additional embodiments are directed to a monolithic optical device. In one or more embodiments, a monolithic optical device comprises: a junction segmented into a plurality of mesas on a common cathode, the junction comprising an n-type layer on the common cathode, an active region on the n-type layer, a p-type layer on the active region, and each of the plurality of mesas separated by a trench; and an anode on the p-type layer of each of the plurality of mesa, the anodes alternating between a photo diode (PD) anode and a light-emitting diode (LED) anode.

Still further embodiments are directed to a monolithic optical device. In one or more embodiments, a monolithic optical device comprises: a junction segmented into a plurality of mesas on a plurality of alternating photo diode (PD) anode and light-emitting diode (LED) anode regions, the junction comprising a p-type layer on the plurality of alternating photo diode (PD) anode and light-emitting diode (LED) anode regions, an active region on the p-type layer, an n-type layer on the active region, and each of the plurality of mesas separated by a trench; and cathode on the n-type layer of each of the plurality of mesas, the cathodes alternating between a photo diode (PD) cathode and a light-emitting diode (LED) cathode.

Additional embodiments of the disclosure are directed to methods on manufacturing a monolithic optical device. In one or more embodiments, a method of manufacturing a monolithic optical device comprises: forming a light-emitting diode (LED) junction on a substrate; forming a semi-insulating layer on the light-emitting diode (LED) junction; and forming a photo diode (PD) junction on the semi-insulating layer to form a vertically stacked monolithic optical device.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limited in the figures of the accompanying drawings in which like references indicate similar elements.

FIG. 1 illustrates a cross-sectional view of an optical device according to one or more embodiments;

FIG. 2 illustrates a cross-sectional view of an optical device according to one or more embodiments;

FIG. 3 illustrates a cross-sectional view of an optical device according to one or more embodiments;

FIG. 4 illustrates a cross-sectional view of an optical device according to one or more embodiments;

FIG. 5 illustrates a cross-sectional view of an optical device according to one or more embodiments;

FIG. 6 illustrates a cross-sectional view of an optical device according to one or more embodiments;

FIG. 7 illustrates a cross-sectional view of an optical device according to one or more embodiments;

FIG. 8 illustrates a cross-sectional view of an optical device according to one or more embodiments;

FIG. 9 is an energy band diagram of MQW with differentiated design for QWs in photodiode depletion region versus QWs in LED depletion region; and

FIG. 10 illustrates a cross-sectional view of an optical device according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate, or on a substrate with one or more films or features or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN, and other alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed is also performed on an underlayer formed on the substrate, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Electrical circuitry can use an electrical power converter to raise or lower a voltage. For example, in a circuit in which a chip uses 2.5 volts for operation, but a power supply supplies 5 volts, the circuit can use an electrical power converter to decrease the voltage by a factor of two. Because electrical power is a product of voltage and current, the electrical power converter can vary the voltage and current simultaneously in a complementary manner. For example, the electrical power converter that decreases the voltage by a factor of two can also increase the current by a factor of two.

Historically, electrical power converters have converted an input direct current (DC) signal into an alternating current (AC), directed the AC signal through a first wire coil, used magnetic induction to induce an AC current in a second wire coil placed in proximity to the first wire coil, and rectified the AC current from the second wire coil to produce an output DC electrical signal. Over the years, as circuitry became denser, the electrical interference from these induction-based electrical power converters became problematic. In addition, ripple in the voltage and/or the current from the rectifying process may also be problematic.

Optical-based electrical power converters can overcome the drawbacks of induction-based electrical power converters. An optical-based electrical power converter can generate light in response to an input electrical signal, can absorb the light, and can generate an output electrical signal in response to the absorbed light. During operation, the light can be fully contained within the electrical power converter, such that the electrical power converter includes only electrical signals (e.g., voltages and/or currents) as its input and output signals.

Embodiments are directed to optical transformer devices having a high power efficiency. In one or more embodiments, the device architecture provides uniform current spreading to minimize efficiency droop. In one or more embodiments, the quantum well designs are optimized for both light-emitting diode (LED) and photo diode (PD) operation. A low-loss optical cavity allows efficient transfer of light from the LED junction to the PD junction. The architecture of one or more embodiments, provides a low-loss voltage up- and down-conversion, and provides compatibility with production-grade epitaxial growth and wafer fabrication processes.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, LED fabrication processes, techniques, materials, equipment, etc., have not been described in great details to avoid unnecessarily obscuring of this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

One or more embodiments provide a vertical device architecture comprising a GaN-based epitaxial layer stack containing the LED and PD junctions and capped with top and bottom reflectors which may also serve as contacts for the LED, PD, or both. In one or more embodiments, the device has separate junctions for the LED and PD, enabling galvanic isolation by a semi-insulating GaN or AlGaN layer between the junctions. In other embodiments, the device uses the same junction for LED and PD, enabling a simpler device design without full galvanic isolation.

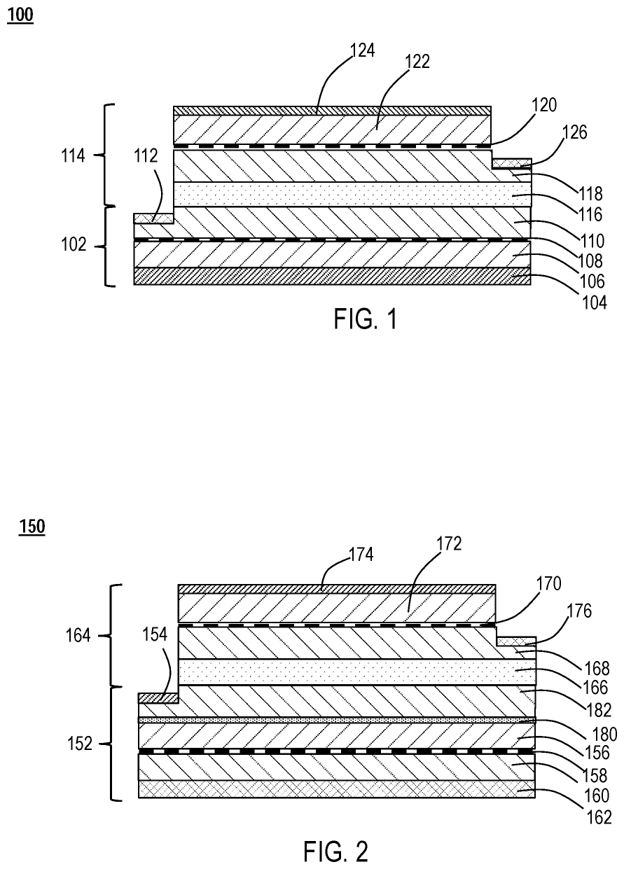

FIGS. 1-8 illustrate cross-section views of light-emitting diode devices according to one or more embodiments. With reference to FIG. 1, in one or more embodiments, separate junctions for the LED 102 and PD 114 are grown vertically in a single monolithic layer structure 100.

In one or more embodiments, the LED 102 and PD 114 include semiconductor layers comprising a III-nitride material, and in specific embodiments epitaxial III-nitride material. In some embodiments, the III-nitride material comprises one or more of gallium (Ga), aluminum (Al), and indium (In). Thus, in some embodiments, the semiconductor layers of the LED 102 and the PD 114 comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like.

In one or more embodiments, the semiconductor layers of the LED 102 comprise a p-type layer 106, an active region 108, and an n-type layer 110. The active region 108 separates the p-type layer 106 from the n-type layer 110. In specific embodiments, the n-type layer 110 and p-type layer 106 of the LED comprise n-doped and p-doped GaN. The semiconductor layers of the LED 102 (i.e., the p-type layer 106, the active region 108, and the n-type layer 110) are on a p-contact 104. The LED includes a p-contact 104 and an n-contact 112.

In one or more embodiments, the semiconductor layers of the PD 114 comprise an n-type layer 118, an active region 120, and a p-type layer 122. The active region 120 separates the p-type layer 122 from the n-type layer 118. In specific embodiments, the n-type layer 118 and p-type layer 122 of the PD 114 comprise n-doped and p-doped GaN. A p-contact 124 is on the semiconductor layers of the PD 114 (i.e., the p-type layer 122, the active region 120, and the n-type layer 118). The PD 114 includes a p-contact 124 and an n-contact 126.

In one or more embodiments, the layers of III-nitride material which form the LED and the PD are grown epitaxially. In one or more embodiments, the substrate is placed in a metalorganic vapor-phase epitaxy (MOVPE) reactor for epitaxy of LED device layers and PD device layers to grow the semiconductor layers. In one or more embodiments, the metal contact layers, the dielectric mirrors, and the like are deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD).

“Sputter deposition” as used herein refers to a physical vapor deposition (PVD) method of thin film deposition by sputtering. In sputter deposition, a material, e.g., a III-nitride, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e., two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein according to some embodiments, “chemical vapor deposition” refers to a process in which films of materials are deposited from the vapor phase by decomposition of chemicals on a substrate surface. In CVD, a substrate surface is exposed to precursors and/or co-reagents simultaneous or substantially simultaneously. As used herein, “substantially simultaneously” refers to either co-flow or where there is overlap for a majority of exposures of the precursors.

As used herein according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. A PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g., a thin film on a substrate. Similar to a thermal ALD process, a purge step maybe conducted between the delivery of each of the reactants.

As used herein according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, the semiconductor layers of the LED 102 and the PD 114 comprise a stack of undoped III-nitride material and doped III-nitride material. The III-nitride materials may be doped with one or more of silicon (Si), oxygen (O), boron (B), phosphorus (P), germanium (Ge), manganese (Mn), or magnesium (Mg) depending upon whether p-type or n-type III-nitride material is needed. In specific embodiments, the semiconductor layers of the LED 102 comprise an n-type layer 110, an active layer 108 and a p-type layer 106, and the semiconductor layers of the PD 114 comprises an n-type layer 118, an active layer 120, and a p-type layer 122.

In one or more embodiments, the semiconductor layers of the LED 102 and of the PD 114 independently have a combined thickness in a range of from about 1 μm to about 10 μm, including a range of from about 1 μm to about 9 μm, 1 μm to about 8 μm, 1 μm to about 7 μm, 1 μm to about 6 μm, 1 μm to about 5 μm, 1 μm to about 4 μm, 1 μm to about 3 μm, 2 μm to about 10 μm, including a range of from about 2 μm to about 9 μm, 2 μm to about 8 μm, 2 μm to about 7 μm, 2 μm to about 6 μm, 2 μm to about 5 μm, 2 μm to about 4 μm, 2 μm to about 3 μm, 3 μm to about 10 μm, 3 μm to about 9 μm, 3 μm to about 8 μm, 3 μm to about 7 μm, 3 μm to about 6 μm, 3 μm to about 5 μm, 3 μm to about 4 μm, 4 μm to about 10 μm, 4 μm to about 9 μm, 4 μm to about 8 μm, 4 μm to about 7 μm, 4 μm to about 6 μm, 4 μm to about 5 μm, 5 μm to about 10 μm, 5 μm to about 9 μm, 5 μm to about 8 μm, 5 μm to about 7 μm, 5 μm to about 6 μm, 6μ m to about 10 μm, 6μ m to about 9 μm, 6 μm to about 8 μm, 6 μm to about 7 μm, 7μ m to about 10 μm, 7 μm to about 9 μm, or 7 μm to about 8 μm.

In one or more embodiments, an active region 108 is formed between the n-type layer 110 and the p-type layer 106 of the LED 102, and an active region 120 is formed between the n-type layer 118 and the p-type layer 122 of the PD 114. The active region 108 and the active region 120 may comprise any appropriate materials known to one of skill in the art. In one or more embodiments, the active region 108 and the active region 120 are independently comprised of a III-nitride material multiple quantum wells (MQW).

In one or more embodiments, the light emitting diode (LED) 102 includes a p-contact 104 and an n-contact 112, and the photo diode (PD) includes a p-contact 124 and an n-contact 126. In one or more embodiments, the p-contact 104, the n-contact 112, the p-contact 124, and the n-contact 126 independently comprise a metal selected from the group consisting of titanium (Ti), aluminum (Al), chromium (Cr), silver (Ag), gold (Ag), and alloys or multilayers thereof.

The LED 102 and PD 114 junctions are separated by a semi-insulating layer 116. The semi-insulating layer 116 may comprise one or more of gallium nitride (GaN) or (AlGaN). Metal doping, e.g., iron (Fe) doping, may be used in the semi-insulating layer 116, similar to GaN power electronics structures.

In one or more embodiments, a main consideration in the design illustrated in FIG. 1 is the high resistivity of p-GaN, necessitating either a continuous contact layer or a dense array of contact vias to achieve good lateral current spreading. In high-power LEDs, this is commonly achieved by growing the LED p-side up and fabricating the contact on top. For the optical transformer of one or more embodiments, with two separate junctions, this is more complicated, as there are two p-type layers that must be contacted. In the embodiment illustrated in FIG. 1, this is done by growing the first junction (LED 102) n-side up and the second junction (PD 114) p-side up. The structure is then processed to deposit the top p-contact 124 and etch and deposit the respective n-contacts 112, 126. Finally, the die 100 is flipped onto a carrier (not illustrated) and the substrate is lifted off to give access to the bottom p-layer for deposition of the second p-contact 104.

In one or more embodiments, since the p-contacts 104, 124 are on the outer surfaces of the die 100, they act both as contacts and reflectors for the optical cavity. Silver is commonly used as a contact metal. Reflectance may be further enhanced by using a dielectric mirror or DBR in front of the contact, with a dense array of vias for electrical contact. N-contact materials with low ohmic resistance can include Al, Ag, and Ti alloys, and transparent conducting oxides such as ZnO.

In one or more embodiments, the monolithic optical device 100 of FIG. 1 includes a light-emitting diode (LED) junction 102, a photo diode (PD) junction 114, and a semi-insulating layer 116 separating the light-emitting diode (LED) junction 102 and the photo diode (PD) junction 112. In one or more embodiments, the light-emitting diode (LED) junction 102, the photo diode (PD) junction 114, and the semi-insulating layer 116 are stacked vertically. In some embodiments, the light-emitting diode (LED) junction 102 comprises an LED p-type layer 106 on an LED p-contact 104, an LED active region 108 on the LED p-type layer 106, an LED n-type layer 110 on the LED active region 108, and an LED n-contact 112 adjacent the LED n-type layer 110. In one or more embodiments, the LED n-type layer 110 is in contact with a first side of the semi-insulating layer 116.

In one or more embodiments, the photo diode (PD) junction 114 of the monolithic optical device 100 comprises a PD n-type layer 118 in contact with a second side of the semi-insulating layer 116, a PD active region 120 on the PD n-type layer 118, a PD p-type layer 122 on the PD active region 120, a PD p-contact 124 on the PD p-type layer 122, and a PD n-contact 126 adjacent the PD n-type layer 118. In one or more embodiments, the PD n-contact 126 and the LED n-contact 112 are on opposite sides of the monolithic optical device 100.

A disadvantage of capping the device 100 illustrated in FIG. 1 with a top p-contact 124 and bottom p-contact 104 may be that it requires either the LED or the PD to be grown p-side down. LEDs are commonly grown n-side down. Manufacturing processes for p-side down structures with high efficiency are challenging to develop. In addition to challenges in growing efficient p-side down LEDs due to Mg incorporation into the active region causing nonradiative recombination, making a good p-contact to p-type GaN after dry etching or laser lift-off is also a challenge due to the resulting surfaces converting to n-type GaN after these processes.

In the embodiment illustrated in FIG. 2, this problem is solved by growing both the LED 152 and PD 164 n-side down and adding a tunnel junction and second middle n-type layer to the p-side of the first device to enable efficient current spreading. In one or more embodiments, separate junctions for the LED 152 and PD 164 are used grown vertically in a single monolithic layer. In one or more embodiments, the LED 152 and PD 164 include semiconductor layers comprising a III-nitride material. In some embodiments, the semiconductor layers of the LED 152 and the PD 164 comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like.

In one or more embodiments, the semiconductor layers of the LED 152 comprise a p-type layer 156, an active region 158, and a first n-type layer 160. With reference to FIG. 2, in one or more embodiments, a tunnel junction 180 is used to cap the p-side of the first junction with a second n-type layer 182 to enable efficient current spreading. As used herein, the term “tunnel junction” refers to a structure that allows electrons to tunnel from the valence band of a p-type layer to the conduction band of an n-type layer in reverse bias. When an electron tunnels, a hole is left behind in the p-type layer, such that carriers are generated in both layers. Accordingly, in an electronic device like a diode, where only a small leakage current flows in reverse bias, a large current can be carried in reverse bias across a tunnel junction. A tunnel junction requires a particular alignment of the conduction and valence bands at the p/n tunnel junction, which has typically been achieved in other materials systems using very high doping (e.g., p++/n++ junction in the (Al)GaAs material system). III-nitride materials have an inherent polarization that creates an electric field at heterointerfaces between different alloy compositions. This polarization field can be utilized to achieve the required band alignment for tunneling.

In one or more embodiments, the active region 158 separates the p-type layer 156 from the first n-type layer 160. In specific embodiments, the first n-type layer 160, the second n-type layer 182, and the p-type layer 156 of the LED 152 comprise n-doped and p-doped GaN. The semiconductor layers of the LED 152 (i.e., the p-type layer 156, the active region 158, the first n-type layer 160, and the second n-type layer 182) are on a n-contact 162. The LED 152 includes a p-contact 154 and an n-contact 162.

In one or more embodiments, the semiconductor layers of the PD 164 comprise an n-type layer 168, an active region 170, and a p-type layer 172. The active region 170 separates the p-type layer 172 from the n-type layer 168. In specific embodiments, the n-type layer 168 and p-type layer 172 of the PD 164 comprise n-doped and p-doped GaN. A p-contact 174 is on the semiconductor layers of the PD 164 (i.e., the p-type layer 172, the active region 170, and the n-type layer 168). The PD 164 includes a p-contact 174 and an n-contact 176.

In one or more embodiments, an active region 158 is formed between the n-type layer 160 and the p-type layer 156 of the LED 152, and an active region 170 is formed between the n-type layer 168 and the p-type layer 172 of the PD 164. The active region 158 and the active region 170 may comprise any appropriate materials known to one of skill in the art. In one or more embodiments, the active region 158 and the active region 170 are independently comprised of a III-nitride material multiple quantum wells (MQW).

In one or more embodiments, the light emitting diode (LED) 152 includes a p-contact 154 and an n-contact 162, and the photo diode (PD) 164 includes a p-contact 174 and an n-contact 176. In some embodiments, the n-contact 162 of the LED 152 is a reflective layer. In one or more embodiments, the p-contact 154, the n-contact 162, the p-contact 174, and the n-contact 176 independently comprise a metal selected from the group consisting of titanium (Ti), aluminum (Al), chromium (Cr), silver (Ag), gold (Ag), and alloys or multilayers thereof.

The LED 152 and PD 164 junctions are separated by a semi-insulating layer 166. The semi-insulating layer 166 may comprise one or more of gallium nitride (GaN) or (AlGaN). Metal doping, e.g., iron (Fe) doping, may be used in the semi-insulating layer 166, similar to GaN power electronics structures.

In one or more embodiments, the monolithic optical device 150 of FIG. 2 includes a light-emitting diode (LED) junction 152, a photo diode (PD) junction 164, and a semi-insulating layer 166 separating the light-emitting diode (LED) junction 152 and the photo diode (PD) junction 164. In one or more embodiments, the light-emitting diode (LED) junction 152, the photo diode (PD) junction 164, and the semi-insulating layer 166 are stacked vertically. In some embodiments, the light-emitting diode (LED) junction 152 comprises an LED n-type layer 160 on an LED n-contact 162. In some embodiments, the LED n-contact 162 may be a reflective layer. In one or more embodiments, an LED active region 158 is on the LED n-type layer 160, an LED p-type layer 156 is on the LED active region 158, an LED tunnel junction 180 is on the LED p-type layer 156, a second LED n-type 182 is on the LED tunnel junction 180, and an LED p-contact 154 is adjacent the second LED n-type layer 182. In one or more embodiments, the second LED n-type layer 182 is in contact with a first side of the semi-insulating layer 166.

In one or more embodiments, the photo diode (PD) junction 114 of the monolithic optical device 100 comprises a PD n-type layer 118 in contact with a second side of the semi-insulating layer 116, a PD active region 120 on the PD n-type layer 118, a PD p-type layer 122 on the PD active region 120, a PD p-contact 124 on the PD p-type layer 122, and a PD n-contact 126 adjacent the PD n-type layer 118. In one or more embodiments, the PD n-contact 126 and the LED n-contact 112 are on opposite sides of the monolithic optical device 100.

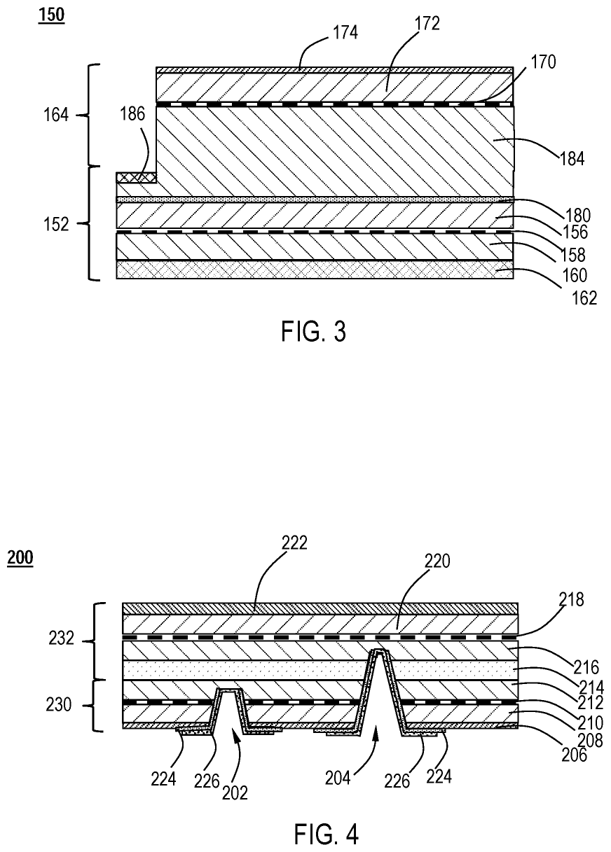

In one or more embodiments, the semi-insulating layer 166 in FIG. 2 may be omitted to create a shared contact device, as illustrated in FIG. 3. Here the shared contact 186 to the middle n-type layer 184 acts both a n-contact for the PD 164 and as p-contact for the LED 152. The embodiment illustrated in FIG. 3 does not allow for galvanic isolation but may be useful for voltage up-conversion or down-conversion when galvanic isolation is not needed.

Similar to the device 150 in FIG. 2, in the device 150 of FIG. 3 separate junctions for the LED 152 and PD 164 are grown vertically in a single monolithic layer. In one or more embodiments, the LED 152 and PD 164 include semiconductor layers comprising a III-nitride material. In some embodiments, the semiconductor layers of the LED 152 and the PD 164 comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like.

In one or more embodiments, the semiconductor layers of the LED 152 comprise a p-type layer 156, an active region 158, and a first n-type layer 160. With reference to FIG. 3, in one or more embodiments, a tunnel junction 180 is used to cap the p-side of the first junction with a second middle n-type layer 184 to enable efficient current spreading. In one or more embodiments, the second middle n-type layer 184 is shared by the LED 152 and the PD 164.

In one or more embodiments, the active region 158 separates the p-type layer 156 from the first n-type layer 160. In specific embodiments, the first n-type layer 160, the second middle n-type layer 184, and the p-type layer 156 of the LED 152 comprise n-doped and p-doped GaN. The semiconductor layers of the LED 152 (i.e., the p-type layer 156, the active region 158, and the first n-type layer 160,) are on a n-contact 162. In one or more embodiments, the n-contact 162 may be a reflective layer. The LED 152 includes a p-contact 154 and an n-contact 162.

In one or more embodiments, the semiconductor layers of the PD 164 comprise an n-type layer 168, an active region 170, and a p-type layer 172. The active region 170 separates the p-type layer 172 from the n-type layer 168. In specific embodiments, the n-type layer 168 and p-type layer 172 of the PD 164 comprise n-doped and p-doped GaN. A p-contact 174 is on the semiconductor layers of the PD 164 (i.e., the p-type layer 172, the active region 170, and the n-type layer 168). The PD 164 includes a p-contact 174 and an n-contact 176.

In one or more embodiments, an active region 158 is formed between the n-type layer 160 and the p-type layer 156 of the LED 152, and an active region 170 is formed between the n-type layer 168 and the p-type layer 172 of the PD 164. The active region 158 and the active region 170 may comprise any appropriate materials known to one of skill in the art. In one or more embodiments, the active region 158 and the active region 170 are independently comprised of a III-nitride material multiple quantum wells (MQW).

In one or more embodiments, the light emitting diode (LED) 152 includes a p-contact 154 and an n-contact 162, and the photo diode (PD) 164 includes a p-contact 174 and an n-contact 176. In some embodiments, the n-contact 162 of the LED 152 is a reflective layer. In one or more embodiments, the p-contact 154, the n-contact 162, the p-contact 174, and the n-contact 176 independently comprise a metal selected from the group consisting of titanium (Ti), aluminum (Al), chromium (Cr), silver (Ag), gold (Ag), and alloys or multilayers thereof.

In one or more embodiments, the monolithic optical device 150 of FIG. 3 includes a light-emitting diode (LED) junction 152, a photo diode (PD) junction 164, and a semi-insulating layer 166 separating the light-emitting diode (LED) junction 152 and the photo diode (PD) junction 164. In one or more embodiments, the light-emitting diode (LED) junction 152, the photo diode (PD) junction 164, and the semi-insulating layer 166 are stacked vertically.

In some embodiments, the light-emitting diode (LED) junction 152 of the monolithic optical device 150 comprises an LED n-type layer 160 on an LED n-contact 162. In some embodiments, the LED n-contact 162 may be a reflective layer. In one or more embodiments, an LED active region 158 is on the LED n-type layer 160, an LED p-type layer 156 is on the LED active region 158, an LED tunnel junction 180 is on the LED p-type layer 156, a second LED n-type 184 is on the LED tunnel junction 180, and contact is adjacent the second LED n-type layer 184. In one or more embodiments, the contact 186 is shared by the light-emitting diode (LED) junction 152 and by the photo diode (PD) junction 164. In one or more embodiments, the contact 186 serves as the n-contact for the photo diode (PD) junction 164 and as the p-contact for the light-emitting diode (LED) junction 152. In one or more embodiments, LED p-type layer 156 is in contact with a first side of the tunnel junction 180, and the second LED n-type layer 184 is in contact with a second side of the tunnel junction 180.

In one or more embodiments, the photo diode (PD) junction 164 of the monolithic optical device 150 comprises a PD active region 170 on the second LED n-type layer 184, a PD p-type layer 172 on the PD active region 170, a PD p-contact 174 on the PD p-type layer 172, and the contact adjacent the LED n-type layer 186. In one

In one or more embodiments, several contact arrangements may be employed to optimize for device performance or fabrication methods. The embodiments illustrated in FIGS. 1-3 rely on lateral current spreading through the n-GaN layers, which is reasonably efficient at lower current densities but may lead to significant current crowding and resulting droop as current density increases.

In an alternative embodiment illustrated in FIG. 4, n-vias 202, 204 may be etched through the p-layer 208 into the respective n-layers 212, 216 to enable more uniform current injection and extraction. This results in a flip-chip device where the bottom p-contact 206 and the n-contacts 224, 226 are directly interconnected to a submount (not illustrated) and the top p-contact 222 is wire bonded.

Referring to FIG. 4, separate junctions for the LED 230 and PD 232 are grown vertically in a single monolithic layer. In one or more embodiments, the LED 230 and PD 232 include semiconductor layers comprising a III-nitride material. In some embodiments, the semiconductor layers of the LED 230 and the PD 232 comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like.

In one or more embodiments, the semiconductor layers of the LED 230 comprise a p-type layer 208, an active region 210, and an n-type layer 212. In one or more embodiments, the active region 210 separates the p-type layer 208 from the n-type layer 212. In specific embodiments, the n-type layer 212 and the p-type layer 208 of the LED 230 comprise n-doped and p-doped GaN. The semiconductor layers of the LED 230 (i.e., the p-type layer 208, the active region 210, and the n-type layer 212,) are on a p-contact 206. The LED 202 includes a via 202 that is etched through the p-type layer 208 into the n-type layer 212. The LED 202 includes a p-contact 206 and an n-contacts 224, 226. In one or more embodiments, the n-contacts 224, 226 are in electrical contact with the p-contact 206.

In one or more embodiments, the semiconductor layers of the PD 232 comprise an n-type layer 216, an active region 218, and a p-type layer 220. The active region 218 separates the p-type layer 220 from the n-type layer 216. In specific embodiments, the n-type layer 216 and p-type layer 220 of the PD 232 comprise n-doped and p-doped GaN. A p-contact 222 is on the semiconductor layers of the PD 232 (i.e., the p-type layer 220, the active region 218, and the n-type layer 216). In one or more embodiments, the PD 232 includes a via 204 that is etched through the p-type layer 208 of the LED and into the n-type layer 216 of the PD 232. The PD 232 includes a p-contact 222 and n-contact 224, 226. In one or more embodiments, the n-contacts 224, 226 are in electrical contact with the p-contact 206 of the LED 230.

In one or more embodiments, an active region 210 is formed between the n-type layer 212 and the p-type layer 208 of the LED 230, and an active region 218 is formed between the n-type layer 216 and the p-type layer 220 of the PD 232. The active region 210 and the active region 218 may comprise any appropriate materials known to one of skill in the art. In one or more embodiments, the active region 210 and the active region 218 are independently comprised of a III-nitride material multiple quantum wells (MQW).

In one or more embodiments, the light emitting diode (LED) 230 includes a p-contact 206 and n-contacts 224, 226, and the photo diode (PD) 232 includes a p-contact 222 and n-contact 224, 226. In one or more embodiments, the p-contact 206, the n-contacts 224, 226, and the p-contact 222 independently comprise a metal selected from the group consisting of titanium (Ti), aluminum (Al), chromium (Cr), silver (Ag), gold (Ag), and alloys or multilayers thereof. The LED 230 and PD 232 junctions are separated by a semi-insulating layer 214. The semi-insulating layer 214 may comprise one or more of gallium nitride (GaN) or (AlGaN). Metal doping, e.g., iron (Fe) doping, may be used in the semi-insulating layer 214, similar to GaN power electronics structures.

In one or more embodiments, the monolithic optical device 200 of FIG. 4 includes a light-emitting diode (LED) junction 230, a photo diode (PD) junction 232, and a semi-insulating layer 214 separating the light-emitting diode (LED) junction 230 and the photo diode (PD) junction 232. In one or more embodiments, the light-emitting diode (LED) junction 230, the photo diode (PD) junction 232, and the semi-insulating layer 214 are stacked vertically. In some embodiments, the light-emitting diode (LED) junction 230 comprises an LED p-type layer 206 on an LED p-contact 204, an LED active region 210 on the LED p-type layer 208, an LED n-type layer 212 on the LED active region 210. In one or more embodiments, the LED n-type layer 212 is in contact with a first side of the semi-insulating layer 214.

In one or more embodiments, the photo diode (PD) junction 232 of the monolithic optical device 200 of FIG. 4 comprises a PD n-type layer 216 in contact with a second side of the semi-insulating layer 214, a PD active region 218 on the PD n-type layer 216, a PD p-type layer 220 on the PD active region 218, and a PD p-contact 222 on the PD p-type layer 220.

In one or more embodiments, the monolithic optical device 200 illustrated in FIG. 4 includes a first via 202 etched into the LED n-type layer 212 and a second via 204 etched into the PD n-type layer 216. In one or more embodiments, least one contact 224, 226 is in the first via 202 and at least one contact 224, 226 is in the second via.

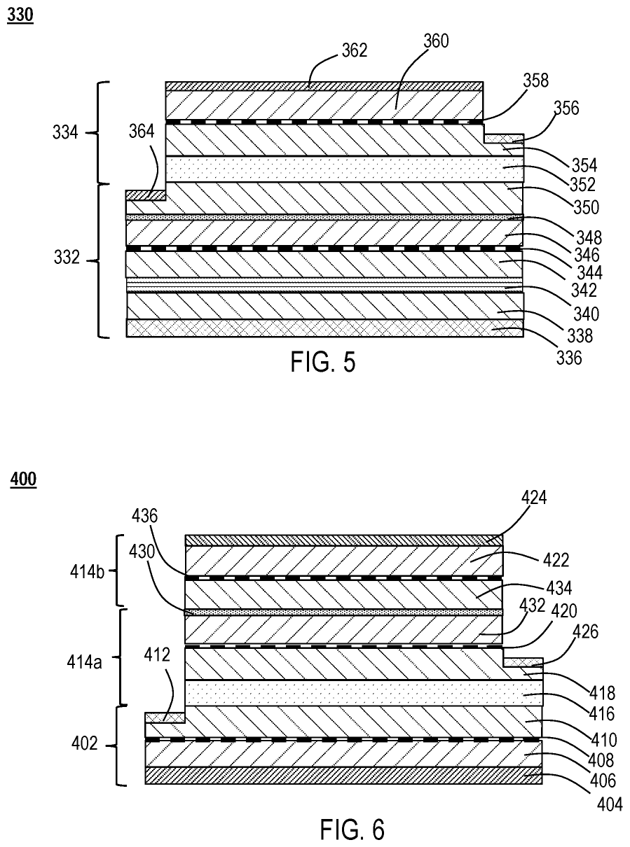

In one or more embodiments, the bottom contact may also be provided through a conductive substrate, eliminating the need to lift the device off the substrate for contact deposition. Growth substrates, however, generally do not have the high reflectivity required for an efficient device. In one or more embodiments, therefore, the problem may be addressed by growing an electrically conductive distributed Bragg reflector (DBR) 340 as part of the device structure, as illustrated in FIG. 5. The DBR 340 may be created by different composition III-nitride layers or by mesoporous structure.

Referring to FIG. 5, separate junctions for the LED 332 and PD 334 are grown vertically in a single monolithic layer. In one or more embodiments, the LED 332 and PD 334 include semiconductor layers comprising a III-nitride material. In some embodiments, the semiconductor layers of the LED 332 and the PD 334 comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like.

In one or more embodiments, the semiconductor layers of the LED 332 comprise a p-type layer 346, an active region 344, a first n-type layer 338, a second n-type layer 342, a third n-type layer 350, and a tunnel junction 348. In one or more embodiments, the active region 344 separates the p-type layer 346 from the second n-type layer 342. In specific embodiments, the p-type layer 346, an active region 344, a first n-type layer 338, a second n-type layer 342, a third n-type layer 350 of the LED 332 comprise n-doped and p-doped GaN. The semiconductor layers of the LED 332 (i.e., p-type layer 346, an active region 344, a first n-type layer 338, a second n-type layer 342, a third n-type layer 350) are on a n-contact 336 or are on a substrate. The LED 332 includes a tunnel junction 340 between the first n-type layer 338 and the second n-type layer 342. The LED 332 includes a p-contact 364 and an n-contact 336.

In one or more embodiments, the semiconductor layers of the PD 334 comprise an n-type layer 354, an active region 358, and a p-type layer 360. The active region 358 separates the p-type layer 360 from the n-type layer 354. In specific embodiments, the n-type layer 354 and p-type layer 360 of the PD 334 comprise n-doped and p-doped GaN. A p-contact 362 is on the semiconductor layers of the PD 334 (i.e., the p-type layer 360, the active region 358, and the n-type layer 354). In one or more embodiments, the PD 334 includes a p-contact 362 and n-contact 356.

In one or more embodiments, an active region 344 is formed between the second n-type layer 342 and the p-type layer 346 of the LED 332, and an active region 358 is formed between the n-type layer 354 and the p-type layer 360 of the PD 334. The active region 344 and the active region 358 may comprise any appropriate materials known to one of skill in the art. In one or more embodiments, the active region 344 and the active region 358 are independently comprised of a III-nitride material multiple quantum wells (MQW).

In one or more embodiments, the light emitting diode (LED) 332 includes a p-contact 364 and an n-contact 336, and the photo diode (PD) 334 includes a p-contact 362 and n-contact 356. In one or more embodiments, the p-contact 364, the n-contacts 336, 356, and the p-contact 362 independently comprise a metal selected from the group consisting of titanium (Ti), aluminum (Al), chromium (Cr), silver (Ag), gold (Ag), and alloys or multilayers thereof.

The LED 332 and PD 334 junctions are separated by a semi-insulating layer 352. The semi-insulating layer 352 may comprise one or more of gallium nitride (GaN) or (AlGaN). Metal doping, e.g., iron (Fe) doping, may be used in the semi-insulating layer 352, similar to GaN power electronics structures.

In one or more embodiments, the monolithic optical device 330 of FIG. 5 includes a light-emitting diode (LED) junction 332, a photo diode (PD) junction 334, and a semi-insulating layer 352 separating the light-emitting diode (LED) junction 332 and the photo diode (PD) junction 334. In one or more embodiments, the light-emitting diode (LED) junction 332, the photo diode (PD) junction 334, and the semi-insulating layer 352 are stacked vertically.

In some embodiments, the light-emitting diode (LED) junction 332 comprises an LED n-type layer 338 on an LED n-contact 336. In some embodiments, the LED n-contact 336 may be a reflective layer. In one or more embodiments, an LED active region 344 is on the LED n-type layer 338, an LED p-type layer 346 is on the LED active region 344, an LED tunnel junction 348 is on the LED p-type layer 346, a second LED n-type 350 is on the LED tunnel junction 348, and an LED p-contact 364 is adjacent the second LED n-type layer 350. In one or more embodiments, the second LED n-type layer 350 is in contact with a first side of the semi-insulating layer 352.

In one or more embodiments, the photo diode (PD) junction 334 of the monolithic optical device 330 comprises a PD n-type layer 354 in contact with a second side of the semi-insulating layer 352, a PD active region 358 on the PD n-type layer 354, a PD p-type layer 360 on the PD active region 358, a PD p-contact 362 on the PD p-type layer 360, and a PD n-contact 356 adjacent the PD n-type layer 354. In one or more embodiments, the PD n-contact 356 and the LED n-contact 364 are on opposite sides of the monolithic optical device 330.

In one or more embodiments, a distributed Bragg reflector 340 and a third LED n-type layer 342 are located between the LED first n-type layer 338 and the LED active region 344.

In one or more embodiments, voltage up- or down-conversion can be achieved by connecting multiple junctions in series in the PD or LED, respectively. This can be done in two ways: at the epi level using tunnel junctions, or at the die level using die segmentation.

FIG. 6 illustrates a voltage up-conversion embodiment with two PD junctions 414a, 414b (multiple quantum well structures) separated by a tunnel junction 430. In one or more embodiments, device 400 of FIG. 6 provides an output voltage that is approximately two times the input voltage, with the exact voltages determined by the MQW design and the voltage drop across the tunnel junction. Higher output voltage can be achieved by stacking more than two PD junctions. Voltage down-conversion can be achieved by applying the same principle on the LED side.

Referring to FIG. 6, separate junctions for the LED 402 and PD 414 are grown vertically in a single monolithic layer. In one or more embodiments, the LED 402 and PD 414 include semiconductor layers comprising a III-nitride material. In some embodiments, the semiconductor layers of the LED 402 and the PD 4144 comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like.

In one or more embodiments, the semiconductor layers of the LED 402 comprise a p-type layer 406, an active region 408, and an n-type layer 410. In one or more embodiments, the active region 408 separates the p-type layer 406 from the n-type layer 410. In specific embodiments, the p-type layer 406, an active region 408, and an n-type layer 410 of the LED 402 comprise n-doped and p-doped GaN. The semiconductor layers of the LED 402 (i.e., the p-type layer 406, the active region 408, and the n-type layer 410) are on a p-contact 404. The LED 402 includes a p-contact 404 and an n-contact 412.

In one or more embodiments, the semiconductor layers of the PD 414 comprise a first n-type layer 418, a first active region 420, a first p-type layer 432, a tunnel junction 430, a second n-type layer 434, a second active region 436, and a second p-type layer 422. The first active region 420 separates the first p-type layer 432 from the first n-type layer 418. The second active region 436 separates the second p-type layer 422 from the second n-type layer 434. In specific embodiments, the first n-type layer 418, the first active region 420, the first p-type layer 432, the second n-type layer 434, the second active region 432, and the second p-type layer 422 of the PD 414 comprise n-doped and p-doped GaN. A p-contact 424 is on the semiconductor layers of the PD 414. In one or more embodiments, the PD 414 includes a p-contact 424 and n-contact 426.

In one or more embodiments, an active region 408 is formed between the n-type layer 410 and the p-type layer 406 of the LED 402, a first active region 420 is formed between the first n-type layer 418 and the first p-type layer 432 of the PD 414, and a second active region 436 is formed between the second n-type layer 432 and the second p-type layer 422 of the PD 414. The active regions 408, 420, and 436 may comprise any appropriate materials known to one of skill in the art. In one or more embodiments, the active regions 408, 420, and 436 are independently comprised of a III-nitride material multiple quantum wells (MQW).

In one or more embodiments, the light emitting diode (LED) 402 includes a p-contact 404 and an n-contact 412, and the photo diode (PD) 414 includes a p-contact 424 and an n-contact 426. In one or more embodiments, the p-contact 404, the n-contact 412, the p-contact 424, and the n-contact 426 independently comprise a metal selected from the group consisting of titanium (Ti), aluminum (Al), chromium (Cr), silver (Ag), gold (Ag), and alloys or multilayers thereof.

The LED 402 and PD 414 junctions are separated by a semi-insulating layer 416. The semi-insulating layer 416 may comprise one or more of gallium nitride (GaN) or (AlGaN). Metal doping, e.g., iron (Fe) doping, may be used in the semi-insulating layer 416, similar to GaN power electronics structures.

In one or more embodiments, a monolithic optical device 400 includes a light-emitting diode (LED) junction 402, a first photo diode (PD) junction 414a, a second photo diode (PD) junction 414b, a tunnel junction 430 separating the first photo diode (PD) junction 414 and the second photo diode (PD) junction 414b, and a semi-insulating layer 416 separating the light-emitting diode (LED) junction 402 and the first photo diode (PD) junction 414a.

In one or more embodiments, the light-emitting diode (LED) junction 402, the first photo diode (PD) junction 414a, the second photo diode (PD) junction 414b, the tunnel junction 430, and the semi-insulating layer 416 are stacked vertically.

In one or more embodiments, the light-emitting diode (LED) junction 401 of the monolithic optical device 400 illustrated in FIG. 6 includes an LED p-type layer 406 on an LED p-contact 404, an LED active region 408 on the LED p-type layer 406, an LED n-type layer 410 on the LED active region 408, and an LED n-contact adjacent 412 the LED n-type layer 410, the LED n-type layer 410 in contact with a first side of the semi-insulating layer 416.

In one or more embodiments, the first photo diode (PD) junction 414a of the monolithic optical device 400 comprises a first PD n-type layer 418 in contact with a second side of the semi-insulating layer 416, a first PD active region 420 on the first PD n-type layer 418, a first PD p-type layer 432 on the first PD active region 420, and a PD n-contact 426 adjacent the first PD n-type layer 418. In one or more embodiments, the second photo diode (PD) junction 414b comprises a second PD n-type layer 434 on the tunnel junction 430, a second PD active region 436 on the second PD n-type layer 434, a second PD p-type layer 422 on the second PD active region 436, and a PD p-contact 424 on the second PD p-type layer 422.

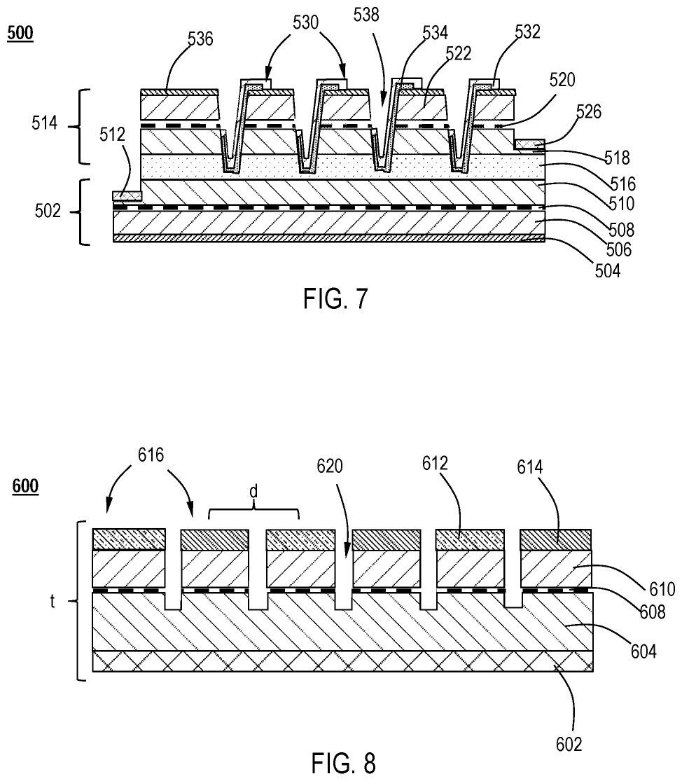

FIG. 7 illustrates a voltage up-conversion embodiment using die segmentation. The PD junction 514 is divided into segments 530 by etching through the active region 520. The segments are then connected in series by wafer-fabricated contacts as schematically shown in the FIG. 7. Metallization designs for such contact schemes are known from high-voltage LEDs. The voltage up-conversion factor is approximately equal to the number of segments. Down-conversion may be achieved by applying segmentation on the LED side.

Referring to FIG. 7, separate junctions for the LED 502 and PD 514 are grown vertically in a single monolithic layer. In one or more embodiments, the LED 502 and PD 514 include semiconductor layers comprising a III-nitride material. In some embodiments, the semiconductor layers of the LED 502 and the PD 514 comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like.

In one or more embodiments, the semiconductor layers of the LED 502 comprise a p-type layer 506, an active region 508, and an n-type layer 510. In one or more embodiments, the active region 508 separates the p-type layer 506 from the n-type layer 510. In specific embodiments, the p-type layer 506, the active region 508, and the n-type layer 510 of the LED 502 comprise n-doped and p-doped GaN. The semiconductor layers of the LED 502 (i.e., the p-type layer 506, the active region 508, and the n-type layer 510) are on a p-contact 504. The LED 502 includes a p-contact 504 and an n-contact 512.

In one or more embodiments, the semiconductor layers of the PD 514 comprise an n-type layer 518, an active region 520, and a p-type layer 522. The active region 520 separates the p-type layer 522 from the n-type layer 518. In specific embodiments, the n-type layer 518, the active region 520, and the p-type layer 522 of the PD 514 comprise n-doped and p-doped GaN. A p-contact 536 is on the semiconductor layers of the PD 514. In one or more embodiments, the PD 514 includes a p-contact 536 and n-contact 526.

In one or more embodiments, an active region 508 is formed between the n-type layer 510 and the p-type layer 506 of the LED 502, and an active region 520 is formed between the n-type layer 518 and the p-type layer 522 of the PD 514. The active regions 508, 520 may comprise any appropriate materials known to one of skill in the art. In one or more embodiments, the active regions 508, 520 are independently comprised of a III-nitride material multiple quantum wells (MQW).

In one or more embodiments, the light emitting diode (LED) 502 includes a p-contact 504 and an n-contact 512, and the photo diode (PD) 514 includes a p-contact 536 and an n-contact 526. In one or more embodiments, the p-contact 504, the n-contact 512, the p-contact 536, and the n-contact 526 independently comprise a metal selected from the group consisting of titanium (Ti), aluminum (Al), chromium (Cr), silver (Ag), gold (Ag), and alloys or multilayers thereof.

The LED 502 and PD 514 junctions are separated by a semi-insulating layer 516. The semi-insulating layer 516 may comprise one or more of gallium nitride (GaN) or (AlGaN). Metal doping, e.g., iron (Fe) doping, may be used in the semi-insulating layer 516, similar to GaN power electronics structures.

In one or more embodiments, the monolithic optical device 500 of FIG. 7 includes a light-emitting diode (LED) junction 502, a photo diode (PD) junction 514, and a semi-insulating layer 516 separating the light-emitting diode (LED) junction 502 and the photo diode (PD) junction 514. In one or more embodiments, the light-emitting diode (LED) junction 502, the photo diode (PD) junction 514, and the semi-insulating layer 516 are stacked vertically. In some embodiments, the light-emitting diode (LED) junction 502 comprises an LED p-type layer 506 on an LED p-contact 504, an LED active region 508 on the LED p-type layer 506, an LED n-type layer 510 on the LED active region 508, and an LED n-contact 512 adjacent the LED n-type layer 510. In one or more embodiments, the LED n-type layer 510 is in contact with a first side of the semi-insulating layer 516.

As illustrated in FIG. 7, in one or more embodiments, the photo diode (PD) junction 514 of the monolithic optical device 500 is segmented into a plurality of photo diode (PD) mesas 530 separated by a trench 538.

In one or more embodiments, each of the plurality of photo diode (PD) mesas 530 comprises a PD n-type layer 518 in contact with a second side of the semi-insulating layer 516, a PD active region 520 on the PD n-type layer 518, a PD p-type layer 522 on the PD active region 520, and a PD p-contact 536 on the PD p-type layer 522. In one or more embodiments, at least one contact 532, 534 is located in the trench 538. The at least one contact 532, 534 may be a conformal contact.

In other embodiments, the same junction (MQW structure) is used both for the LED and the PD as illustrated in FIG. 8. The device 600 of FIG. 8 uses the n-side as a common cathode 602 and relies on the high resistivity of p-GaN 610 to create separate anodes 612, 614 for the PD and LED, respectively. There is no galvanic isolation in the embodiment illustrated in FIG. 8, as the cathode 602 is shared, but it is possible to achieve voltage up- or down-conversion by using a tunnel junction stacked design, where the additional junctions are etched away in the areas where the LED or PD anodes are deposited.

The embodiment illustrated in FIG. 8 requires light generated in the LED parts of the junction to spread laterally to the PD parts of the junction. In order to minimize the number of internal reflections and optimize device efficiency, in one or more embodiments, the LED anodes 614 and the PD anodes 612 are densely intertwined. In one or more embodiments, the center-to-center spacing, d, between LED anodes 614 and PD anodes 612 may be less than twenty times, less than ten times, or less than five times the thickness, t, of the device 600.

In such designs as illustrated in FIG. 8, where a single MQW structure fulfills both LED and PD functions, the MQW design must consider both operating modes. The MQW could be designed (by doping profile and structure) such that the active region structure 608 within the depletion region during operation is different between the LED and PD operation to provide some ability to optimize for the LED and PD independently.

In one or more embodiments, a monolithic optical device 600 comprises a junction segmented into a plurality of mesas 616 on a common cathode 602. In one or more embodiments, the junction includes an n-type layer 604 on the common cathode 602, an active region 608 on the n-type layer 604, and a p-type layer 610 on the active region 608. In one or more embodiments, each of the plurality of mesas 616 is separated by a trench 620. In one or more embodiments, an anode 612, 614 is located on the p-type layer 610 of each of the plurality of mesas 616. In one or more embodiments, the anodes 612, 614 alternate between a photo diode (PD) anode 612 and a light-emitting diode (LED) anode 614.

In one or more embodiments, as illustrated in FIG. 8, the distance, d, between the light-emitting diode (LED) anode 614 and the photo diode (PD) anode 612 of the monolithic optical device 60 is less than twenty times a thickness, t, of the monolithic optical device 600.

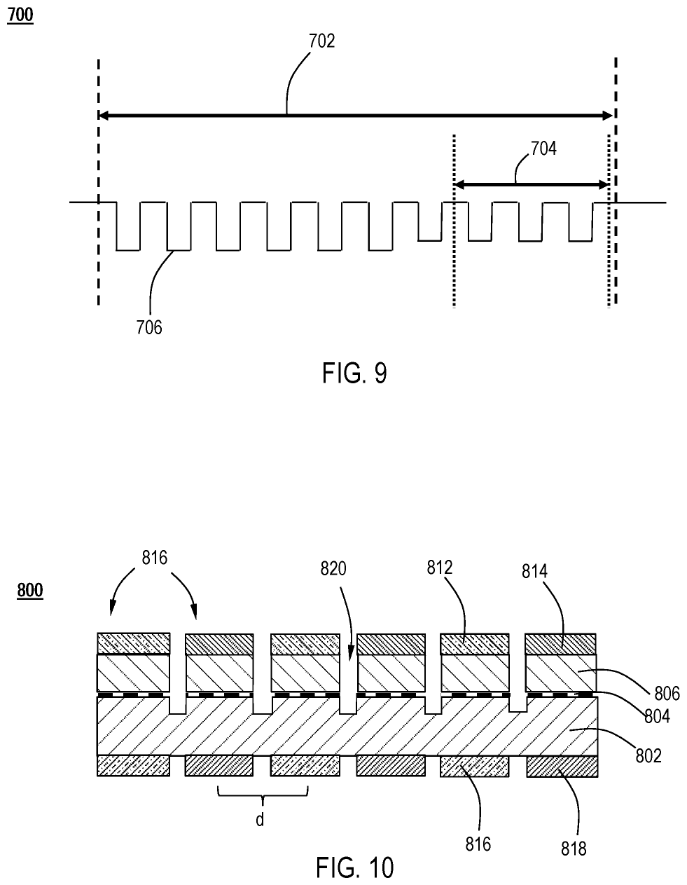

FIG. 9 is an energy band diagram of MQW with differentiated design for QWs in photodiode depletion region versus QWs in LED depletion region. As illustrated in FIG. 9, in one or more embodiments, the quantum wells 706 that are in the PD depletion region 702 but are outside the LED depletion region 704 could have lower energy to help with photon absorption.

In one or more embodiments, the same junction (MQW structure) is used both for the LED and the PD as illustrated in FIG. 10. The device 800 of FIG. 10 uses a single multiple quantum well 804 to allow bidirectional operation of the device 800. In one or more embodiments, the high resistivity of p-GaN 802 create separate anodes 816, 818 for the PD and LED, respectively. Galvanic isolation in the embodiment illustrated in FIG. 10 may be compromised. The n-type layer 806 creates separate cathodes 812, 814 for the PD and LED, respectively.

The embodiment illustrated in FIG. 10 requires light generated in the LED parts of the junction to spread laterally to the PD parts of the junction. In order to minimize the number of internal reflections and optimize device efficiency, in one or more embodiments, the LED anodes 818 and the PD anodes 816 are densely intertwined. In one or more embodiments, the center-to-center spacing, d, between LED anodes 818 and PD anodes 816 may be less than 20×, less, than 10×, or less than 5× the thickness of the device 600.

In such designs as illustrated in FIG. 10, where a single MQW structure fulfills both LED and PD functions, the MQW design must consider both operating modes. The MQW could be designed (by doping profile and structure) such that the active region structure 804 within the depletion region during operation is different between the LED and PD operation to provide some ability to optimize for the LED and PD independently. For example, the PD depletion region may extend beyond the LED depletion region, and the QWs in the extended depletion region may have lower energy to help with photon absorption in the PD.

As illustrated in FIG. 10, in one or more embodiments, a monolithic optical device 800 comprises a junction segmented into a plurality of mesas 816 on a plurality of alternating photo diode (PD) anode 816 and light-emitting diode (LED) anode regions 818. In one or more embodiments, the junction comprises a p-type layer 802 on the plurality of alternating photo diode (PD) anode 816 and light-emitting diode (LED) anode regions 818, an active region 804 on the p-type layer 802, and an n-type layer 806 on the active region 804. In one or more embodiments, each of the plurality of mesas 816 are separated by a trench 820. In one or more embodiments, a cathode 812, 814 is on the n-type layer 806 of each of the plurality of mesas 816. The cathodes 812, 814 alternate between a photo diode (PD) cathode 812 and a light-emitting diode (LED) cathode 814.

Additional embodiments may be formed by combining elements described above. Furthermore, while junctions are marked as LED and PD, it should be understood that these are generally interchangeable, i.e., either the LED or the PD structure can be grown first. With a suitable MQW design, the device can also be operated bidirectionally, where either junction can act as LED or PD depending on the external bias.

### EMBODIMENTS

Various embodiments are listed below. It will be understood that the embodiments listed below may be combined with all aspects and other embodiments in accordance with the scope of the invention.

Embodiment (a). A monolithic optical device comprising: a light-emitting diode (LED) junction; a first photo diode (PD) junction; a second photo diode (PD) junction; a tunnel junction separating the first photo diode (PD) junction and the second photo diode (PD) junction; and a semi-insulating layer separating the light-emitting diode (LED) junction and the first photo diode (PD) junction, wherein the light-emitting diode (LED) junction, the first photo diode (PD) junction, the second photo diode (PD) junction, the tunnel junction, and the semi-insulating layer are stacked vertically.

Embodiment (b). The monolithic optical device of embodiment (a), wherein the light-emitting diode (LED) junction comprises an LED p-type layer on an LED p-contact, an LED active region on the LED p-type layer, an LED n-type layer on the LED active region, and an LED n-contact adjacent the LED n-type layer, the LED n-type layer in contact with a first side of the semi-insulating layer.

Embodiment (c). The monolithic optical device of embodiment (a) to embodiment (b), wherein the first photo diode (PD) junction comprises a first PD n-type layer in contact with a second side of the semi-insulating layer, a first PD active region on the first PD n-type layer, a first PD p-type layer on the first PD active region, and a PD n-contact adjacent the first PD n-type layer, and wherein the second photo diode (PD) junction comprises a second PD n-type layer on the tunnel junction, a second PD active region on the second PD n-type layer, a second PD p-type layer on the second PD active region, and a PD p-contact on the second PD p-type layer.

Embodiment (d). A method of manufacturing the monolithic optical device of embodiment (a) to embodiment (c), the method comprising: forming a light-emitting diode (LED) junction on a substrate; forming a semi-insulating layer on the light-emitting diode (LED) junction; forming a first photo diode (PD) junction on the semi-insulating layer; forming a tunnel junction on the first photo diode (PD) junction; and forming a second photo diode (PD) junction on the tunnel junction to form a vertically stacked monolithic optical device.

Embodiment (e). The method of embodiment (d), wherein forming the light-emitting diode (LED) junction comprises: forming an LED p-type layer on an LED p-contact; forming an LED active region on the LED p-type layer; forming an LED n-type layer on the LED active region; and forming an LED n-contact adjacent the LED n-type layer, the LED n-type layer in contact with a first side of the semi-insulating layer.

Embodiment (f). The method of embodiment (d) to embodiment (e), wherein forming the first photo diode (PD) junction comprises: forming a first PD n-type layer in contact with a second side of the semi-insulating layer; forming a first PD active region on the first PD n-type layer; forming a first PD p-type layer on the first PD active region; and forming a PD n-contact adjacent the first PD n-type layer.

Embodiment (g). The method of embodiment (d) to embodiment (f), wherein forming the second photo diode (PD) junction comprises: forming a second PD n-type layer on the tunnel junction; forming a second PD active region on the second PD n-type layer; forming a second PD p-type layer on the second PD active region; and forming a PD p-contact on the second PD p-type layer.

Embodiment (h). A monolithic optical device comprising: a junction segmented into a plurality of mesas on a common cathode; and an anode on each of the plurality of mesas, the anodes alternating between a photo diode (PD) anode and a light-emitting diode (LED) anode.

Embodiment (i). The monolithic optical device of embodiment (h), wherein the junction comprises: an n-type layer on the common cathode; an active region on the n-type layer; a p-type layer on the active region; and each of the plurality of mesas separated by a trench.

Embodiment (j). The monolithic optical device of embodiment (h) to embodiment (i), wherein the anode is on the p-type layer of each of the plurality of mesas.

Embodiment (k). The monolithic optical device of embodiment (h) to embodiment (j), wherein a distance between the light-emitting diode (LED) anode and the photo diode (PD) anode is less than twenty times a thickness of the monolithic optical device.

Embodiment (l). A method of manufacturing the monolithic optical device of embodiment (h) to embodiment (k), the method comprising: forming a junction on a common cathode, the junction segmented into a plurality of mesas; and forming an anode on each of the plurality of mesas, the anodes alternating between a photo diode (PD) anode and a light-emitting diode (LED) anode.

Embodiment (m). The method of embodiment (l), wherein forming the junction comprises: forming an n-type layer on the common cathode; forming an active region on the n-type layer; forming a p-type layer on the active region; and forming the plurality of mesas separated by a trench.

Embodiment (n). The method of embodiment (l) to embodiment (m), wherein the anode is formed on the p-type layer on each of the plurality of mesas.

Embodiment (o). A monolithic optical device comprising: a junction segmented into a plurality of mesas on a plurality of alternating photo diode (PD) anode and light-emitting diode (LED) anode regions; and a cathode on each of the plurality of mesas, the cathodes alternating between a photo diode (PD) cathode and a light-emitting diode (LED) cathode.

Embodiment (p). The monolithic optical device of embodiment (o), wherein the junction comprises: a p-type layer on the plurality of alternating photo diode (PD) anode and light-emitting diode (LED) anode regions; an active region on the p-type layer; an n-type layer on the active region; and each of the plurality of mesas separated by a trench.

Embodiment (q). The monolithic device of embodiment (o) to embodiment (p), wherein the cathode is on the n-type layer of each of the plurality of mesas.

Embodiment (r). A method of manufacturing the monolithic optical device of embodiment (o) to embodiment (q), the method comprising: forming a junction on a plurality of alternating photo diode (PD) anode and light-emitting diode (LED) anode regions, the junction segmented into a plurality of mesas; and forming cathode on each of the plurality of mesas, the cathodes alternating between a photo diode (PD) cathode and a light-emitting diode (LED) cathode.

Embodiment(s). The method of embodiment (r), wherein forming the junction comprises: forming a p-type layer on the plurality of alternating photo diode (PD) anode and light-emitting diode (LED) anode regions; forming an active region on the p-type layer; forming an n-type layer on the active region; and forming the plurality of mesas separated by a trench.

Embodiment (t). The method of embodiment (r) to embodiment(s), wherein the cathode is formed on the n-type layer of each of the plurality of mesas.

Embodiment (u). A monolithic optical device comprising: a light-emitting diode (LED) junction; a photo diode (PD) junction; and a semi-insulating layer separating the light-emitting diode (LED) junction and the photo diode (PD) junction, wherein the light-emitting diode (LED) junction, the photo diode (PD) junction, and the semi-insulating layer are stacked vertically.

Embodiment (v). The monolithic optical device of embodiment (u), wherein the light-emitting diode (LED) junction comprises an LED p-type layer on an LED p-contact, an LED active region on the LED p-type layer, an LED n-type layer on the LED active region, and an LED n-contact adjacent the LED n-type layer, the LED n-type layer in contact with a first side of the semi-insulating layer.

Embodiment (w). The monolithic optical device of embodiment (u), wherein the light-emitting diode (LED) junction comprises an LED n-type layer on an LED n-contact, an LED active region on the LED n-type layer, an LED p-type layer on the LED active region, an LED tunnel junction on the LED p-type layer, a second LED n-type on the LED tunnel junction, and an LED p-contact adjacent the second LED n-type layer, the second LED n-type layer in contact with a first side of the semi-insulating layer.

Embodiment (x). The monolithic optical device of embodiment (u) to embodiment (w), wherein the photo diode (PD) junction comprises a PD n-type layer in contact with a second side of the semi-insulating layer, a PD active region on the PD n-type layer, a PD p-type layer on the PD active region, a PD p-contact on the PD p-type layer, and a PD n-contact adjacent the PD n-type layer.

Embodiment (y). The monolithic device of embodiment (u) to embodiment (x), further comprising a distributed Bragg reflector and a third LED n-type layer on the LED first n-type layer.

Embodiment (z). The monolithic optical device of embodiment (u), wherein the light-emitting diode (LED) junction comprises an LED p-type layer on an LED p-contact, an LED active region on the LED p-type layer, an LED n-type layer on the LED active region, the LED n-type layer in contact with a first side of the semi-insulating layer, and wherein the photo diode (PD) junction comprises a PD n-type layer in contact with a second side of the semi-insulating layer, a PD active region on the PD n-type layer, a PD p-type layer on the PD active region, and a PD p-contact on the PD p-type layer.

Embodiment (aa). The monolithic optical device of embodiment (u) to embodiment (z), further comprising a first via etched into the LED n-type layer and a second via etched into the PD n-type layer.

Embodiment (bb). The monolithic optical device of embodiment (u) to embodiment (aa), further comprising at least one contact in the first via and at least one contact in the second via.

Embodiment (cc) The monolithic optical device of embodiment (v), wherein the photo diode (PD) junction is segmented into a plurality of photo diode (PD) mesas separated by a trench.

Embodiment (dd). The monolithic optical device of embodiment (cc), wherein each of the plurality of photo diode (PD) mesas comprises a PD n-type layer in contact with a second side of the semi-insulating layer, a PD active region on the PD n-type layer, a PD p-type layer on the PD active region, and a PD p-contact on the PD p-type layer.

Embodiment (ee). The monolithic optical device of embodiment (cc) to embodiment (dd), further comprising a contact in the trench.

Embodiment (ff). A monolithic optical device comprising: a light-emitting diode (LED) junction; a photo diode (PD) junction; a tunnel junction, and a contact shared by the light-emitting diode (LED) junction and the photo diode (PD) junction, wherein the light-emitting diode (LED) junction, the photo diode (PD) junction, and the tunnel junction are stacked vertically.

Embodiment (gg). The monolithic optical device of embodiment (ff), wherein the light-emitting diode (LED) junction comprises an LED n-type layer on an LED n-contact, an LED active region on the LED n-type layer, an LED p-type layer on the LED active region, an LED tunnel junction on the LED p-type layer, a second LED n-type on the LED tunnel junction, the contact adjacent the second LED n-type layer.

Embodiment (hh). The monolithic optical device of embodiment (ff) to embodiment (gg), wherein the photo diode (PD) junction comprises a PD active region on the second LED n-type layer, a PD p-type layer on the PD active region, a PD p-contact on the PD p-type layer, and the contact adjacent the LED n-type layer.

Embodiment (ii). A method of manufacturing a monolithic optical device, the method comprising: forming a light-emitting diode (LED) junction on a substrate; forming a semi-insulating layer on the light-emitting diode (LED) junction; and forming a photo diode (PD) junction on the semi-insulating layer to form a vertically stacked monolithic optical device.

Embodiment (jj). The method of embodiment (ii), wherein forming the light-emitting diode (LED) junction comprises: forming an LED p-type layer on an LED p-contact; forming an LED active region on the LED p-type layer; forming an LED n-type layer on the LED active region; and forming an LED n-contact adjacent the LED n-type layer, the LED n-type layer in contact with a first side of the semi-insulating layer.

Embodiment (kk). The method of embodiment (ii), wherein forming the light-emitting diode (LED) junction comprises: forming an LED n-type layer on an LED n-contact; forming an LED active region on the LED n-type layer; forming an LED p-type layer on the LED active region; forming an LED tunnel junction on the LED p-type layer; forming a second LED n-type on the LED tunnel junction; and forming an LED p-contact adjacent the second LED n-type layer, the second LED n-type layer in contact with a first side of the semi-insulating layer.

Embodiment (ll). The method of embodiment (ii), further comprising segmenting the photo diode (PD) junction into a plurality of photo diode (PD) mesas separated by a trench.

Embodiment (mm). The method of embodiment (ll), further comprising forming a contact in the trench.

Embodiment (nn). The method of embodiment (ii), wherein forming the light-emitting diode (LED) junction comprises: forming an LED p-type layer on an LED p-contact, forming an LED active region on the LED p-type layer, forming an LED n-type layer on the LED active region, the LED n-type layer in contact with a first side of the semi-insulating layer; and forming the photo diode (PD) junction comprises: forming a PD n-type layer in contact with a second side of the semi-insulating layer, forming a PD active region on the PD n-type layer, forming a PD p-type layer on the PD active region, and forming a PD p-contact on the PD p-type layer.

Embodiment (oo). The method of embodiment (ii) to embodiment (nn), further comprising etching a first via into the LED n-type layer and etching a second via into the PD n-type layer.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.

Reference throughout this specification to a layer, region, or substrate as being “on” or extending “onto” another element, means that it may be directly on or extend directly onto the other element or intervening elements may also be present. When an element is referred to as being “directly on” or extending “directly onto” another element, there may be no intervening elements present. Furthermore, when an element is referred to as being “connected” or “coupled” to another element, it may be directly connected or coupled to the other element and/or connected or coupled to the other element via one or more intervening elements. When an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1.-20. (canceled)

21. A monolithic optical device comprising:
a light-emitting diode (LED) junction;
a photo diode (PD) junction; and
a semi-insulating layer separating the light-emitting diode (LED) junction and the photo diode (PD) junction,
wherein the light-emitting diode (LED) junction, the photo diode (PD) junction, and the semi-insulating layer are stacked vertically.

22. The monolithic optical device of claim 21, wherein the light-emitting diode (LED) junction comprises an LED p-type layer on an LED p-contact, an LED active region on the LED p-type layer, an LED n-type layer on the LED active region, and an LED n-contact adjacent the LED n-type layer, the LED n-type layer in contact with a first side of the semi-insulating layer.

23. The monolithic optical device of claim 21, wherein the light-emitting diode (LED) junction comprises an LED n-type layer on an LED n-contact, an LED active region on the LED n-type layer, an LED p-type layer on the LED active region, an LED tunnel junction on the LED p-type layer, a second LED n-type on the LED tunnel junction, and an LED p-contact adjacent the second LED n-type layer, the second LED n-type layer in contact with a first side of the semi-insulating layer.

24. The monolithic optical device of claim 22, wherein the photo diode (PD) junction comprises a PD n-type layer in contact with a second side of the semi-insulating layer, a PD active region on the PD n-type layer, a PD p-type layer on the PD active region, a PD p-contact on the PD p-type layer, and a PD n-contact adjacent the PD n-type layer.

25. The monolithic device of claim 24, further comprising a distributed Bragg reflector and a third LED n-type layer on the LED first n-type layer.

26. The monolithic optical device of claim 21, wherein the light-emitting diode (LED) junction comprises an LED p-type layer on an LED p-contact, an LED active region on the LED p-type layer, an LED n-type layer on the LED active region, the LED n-type layer in contact with a first side of the semi-insulating layer, and wherein the photo diode (PD) junction comprises a PD n-type layer in contact with a second side of the semi-insulating layer, a PD active region on the PD n-type layer, a PD p-type layer on the PD active region, and a PD p-contact on the PD p-type layer.

27. The monolithic optical device of claim 25, further comprising a first via etched into the LED n-type layer and a second via etched into the PD n-type layer.

28. The monolithic optical device of claim 26, further comprising at least one contact in the first via and at least one contact in the second via.

29. The monolithic optical device of claim 22, wherein the photo diode (PD) junction is segmented into a plurality of photo diode (PD) mesas separated by a trench.

30. The monolithic optical device of claim 29, wherein each of the plurality of photo diode (PD) mesas comprises a PD n-type layer in contact with a second side of the semi-insulating layer, a PD active region on the PD n-type layer, a PD p-type layer on the PD active region, and a PD p-contact on the PD p-type layer.

31. The monolithic optical device of claim 30, further comprising a contact in the trench.

32. A monolithic optical device comprising:
a light-emitting diode (LED) junction;
a photo diode (PD) junction;
a tunnel junction, and
a contact shared by the light-emitting diode (LED) junction and the photo diode (PD) junction,
wherein the light-emitting diode (LED) junction, the photo diode (PD) junction, and the tunnel junction are stacked vertically.

33. The monolithic optical device of claim 32, wherein the light-emitting diode (LED) junction comprises an LED n-type layer on an LED n-contact, an LED active region on the LED n-type layer, an LED p-type layer on the LED active region, an LED tunnel junction on the LED p-type layer, a second LED n-type on the LED tunnel junction, the contact adjacent the second LED n-type layer.

34. The monolithic optical device of claim 33, wherein the photo diode (PD) junction comprises a PD active region on the second LED n-type layer, a PD p-type layer on the PD active region, a PD p-contact on the PD p-type layer, and the contact adjacent the LED n-type layer.

35. A monolithic optical device comprising:
a light-emitting diode (LED) junction;
a first photo diode (PD) junction;
a second photo diode (PD) junction;
a tunnel junction separating the first photo diode (PD) junction and the second photo diode (PD) junction; and
a semi-insulating layer separating the light-emitting diode (LED) junction and the first photo diode (PD) junction,
wherein the light-emitting diode (LED) junction, the first photo diode (PD) junction, the second photo diode (PD) junction, the tunnel junction, and the semi-insulating layer are stacked vertically.

36. The monolithic optical device of claim 35, wherein the light-emitting diode (LED) junction comprises an LED p-type layer on an LED p-contact, an LED active region on the LED p-type layer, an LED n-type layer on the LED active region, and an LED n-contact adjacent the LED n-type layer, the LED n-type layer in contact with a first side of the semi-insulating layer.

37. The monolithic optical device of claim 36, wherein the first photo diode (PD) junction comprises a first PD n-type layer in contact with a second side of the semi-insulating layer, a first PD active region on the first PD n-type layer, a first PD p-type layer on the first PD active region, and a PD n-contact adjacent the first PD n-type layer, and wherein the second photo diode (PD) junction comprises a second PD n-type layer on the tunnel junction, a second PD active region on the second PD n-type layer, a second PD p-type layer on the second PD active region, and a PD p-contact on the second PD p-type layer.

38. A monolithic optical device comprising:
a junction segmented into a plurality of mesas on a common cathode, the junction comprising an n-type layer on the common cathode, an active region on the n-type layer, a p-type layer on the active region, and each of the plurality of mesas separated by a trench; and
an anode on the p-type layer of each of the plurality of mesa, the anodes alternating between a photo diode (PD) anode and a light-emitting diode (LED) anode.

39. The monolithic optical device of claim 38, wherein a distance between the light-emitting diode (LED) anode and the photo diode (PD) anode is less than twenty times a thickness of the monolithic optical device.

40. A monolithic optical device comprising:
a junction segmented into a plurality of mesas on a plurality of alternating photo diode (PD) anode and light-emitting diode (LED) anode regions, the junction comprising a p-type layer on the plurality of alternating photo diode (PD) anode and light-emitting diode (LED) anode regions, an active region on the p-type layer, an n-type layer on the active region, and each of the plurality of mesas separated by a trench; and
cathode on the n-type layer of each of the plurality of mesas, the cathodes alternating between a photo diode (PD) cathode and a light-emitting diode (LED) cathode.
